(19) United States
(12) Patent Application Publication
(10) Pub. No.: US 2015/0004275 A1
(43) Pub. Date: Jan. 1, 2015

(54) MOLD

(71) Applicant: CANON KABUSHIKI KAISHA, TOKYO (JP)

(72) Inventors: Yoshikazu Miyajima, Utsunomiya-shi (JP); Akiyoshi Suzuki, Tokyo (JP); Takehiko Iwanaga, Sakura-shi (JP)

(21) Appl. No.: 14/311,759

(22) Filed: Jun. 23, 2014

(30) Foreign Application Priority Data
Jun. 26, 2013 (JP) 2013-134209

(51) Int. Cl. G03F 7/00

(52) U.S. Cl. CPC G03F 7/0002
USPC 425/385

(57) ABSTRACT

The present invention provides a mold including a pattern to be transferred to a resin coated on a substrate, by performing an imprint process, the mold comprising a first portion including a first surface which include a pattern portion provided with the pattern and a peripheral portion surrounding the pattern portion, and a second surface which is opposite to the first surface, and a second portion which surrounds the first portion and is thicker than the first portion, wherein a concave portion is formed by the second surface of the first portion and an inner surface of the second portion, and the concave portion is provided with a light-shielding portion in a region on an opposite side to the peripheral portion.

### BACKGROUND OF THE INVENTION

1. Field of the Invention

The present invention relates to a mold used for an imprint process.

2. Description of the Related Art

An imprint technique of transferring a pattern formed on a mold onto a substrate has attracted attention as one of the lithography techniques used for the manufacture of semiconductor devices. An imprint apparatus using such a technique cures a resin (imprint material) supplied onto a substrate by irradiating the resin with light while the resin and a mold on which a pattern is formed are in contact with each other. It is possible to transfer the mold pattern onto the substrate by releasing the mold from the cured resin.

In such an imprint apparatus, when applying light to a shot region onto which a mold pattern is to be transferred, a peripheral region is also irradiated with light, and a resin applied to a peripheral region is sometimes cured. This may make it difficult to accurately align the mold and the substrate because of the influence of the curing of the resin in the peripheral region when performing an imprint process for a shot region adjacent to the above mentioned shot region. Under the circumstance, Japanese Patent Laid-Open No. 2009-212449 has proposed a method of shielding light to prevent a peripheral region from being irradiated with light.

According to Japanese Patent Laid-Open No. 2009-212449, a member which shields light is provided on the rear surface of a mold (the surface opposite to the surface on which a pattern is formed). Since the mold is held on its side surface, the mold is formed thick to prevent the distortion of a pattern caused by the weight of the mold. This increases the distance between the member which shields light and the pattern on the mold, and hence may make it difficult to accurately define a region on the substrate to be irradiated with light.

### SUMMARY OF THE INVENTION

The present invention provides a technique advantageous in accurately defining a region on a substrate to be irradiated with light when performing an imprint process.

According to one aspect of the present invention, there is provided a mold including a pattern to be transferred to a resin coated on a substrate, by performing an imprint process, the mold comprising: a first portion including a first surface which include a pattern portion provided with the pattern and a peripheral portion surrounding the pattern portion, and a second surface which is opposite to the first surface; and a second portion which surrounds the first portion and is thicker than the first portion, wherein a concave portion is formed by the second surface of the first portion and an inner surface of the second portion, and the concave portion is provided with a light-shielding portion in a region on an opposite side to the peripheral portion.

Further features of the present invention will become apparent from the following description of exemplary embodiments with reference to the attached drawings.

### BRIEF DESCRIPTION OF THE DRAWINGS

FIG. 1 is a view showing an imprint apparatus according to the first embodiment;

FIG. 2A is a view showing a mold according to the first embodiment;

FIG. 2B is a view showing the mold according to the first embodiment;

FIG. 3 is a view for explaining a procedure for an imprint process in the imprint apparatus according to the first embodiment;

FIG. 4 is a view for explaining a procedure for an imprint process in the imprint apparatus according to the first embodiment;

FIG. 5A is a view for explaining a problem in an imprint process;

FIG. 5B is a view for explaining a problem in an imprint process;

FIG. 6 is a view for explaining a problem in an imprint process;

FIG. 7A is a view showing a light-shielding film as a light-shielding portion in the first embodiment;

FIG. 7B is a view showing the light-shielding film as the light-shielding portion in the first embodiment;

FIG. 8 is a view showing the light-shielding film as the light-shielding portion in the first embodiment;

FIG. 9A is a view showing an example of another arrangement of the light-shielding film;

FIG. 9B is a view showing an example of still another arrangement of the light-shielding film;

FIG. 10A is a view showing an example of still another arrangement of the light-shielding film;

FIG. 10B is a view showing an example of still another arrangement of the light-shielding film;

FIG. 11A is a view showing a light-shielding member as a light-shielding portion in the second embodiment; and

FIG. 11B is a view showing the light-shielding member as the light-shielding portion in the second embodiment.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

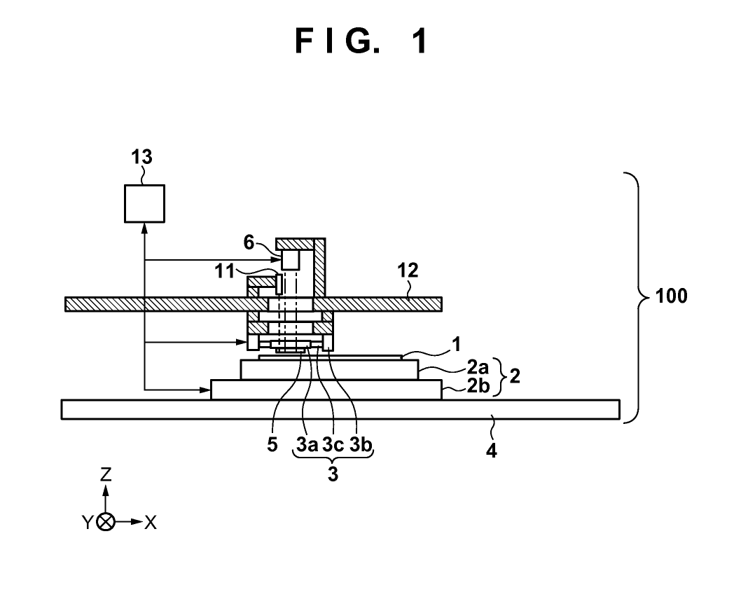

An imprint apparatus 100 according to the first embodiment of the present invention will be described with reference to FIG. 1. The imprint apparatus 100 is used to manufacture semiconductor devices and the like. The imprint apparatus 100 cures a resin 14 (imprint material) on a substrate 1 by irradiating the resin with light while a mold 5 on which a concave/convex pattern is formed is in contact with the resin 14. The imprint apparatus 100 can transfer the pattern onto the substrate 1 by releasing the mold 5 from the cured resin 14 upon increasing the interval between the mold 5 and the substrate 1. The imprint apparatus 100 according to the first embodiment uses, as the resin 14, an ultraviolet curable resin which is cured by being irradiated with ultraviolet light. However, the embodiment is not limited to this. For example, the embodiment may use a resin which is cured by being irradiated with light having a wavelength other than that of ultraviolet light or a resin which is cured by heat generated upon irradiation with infrared light.

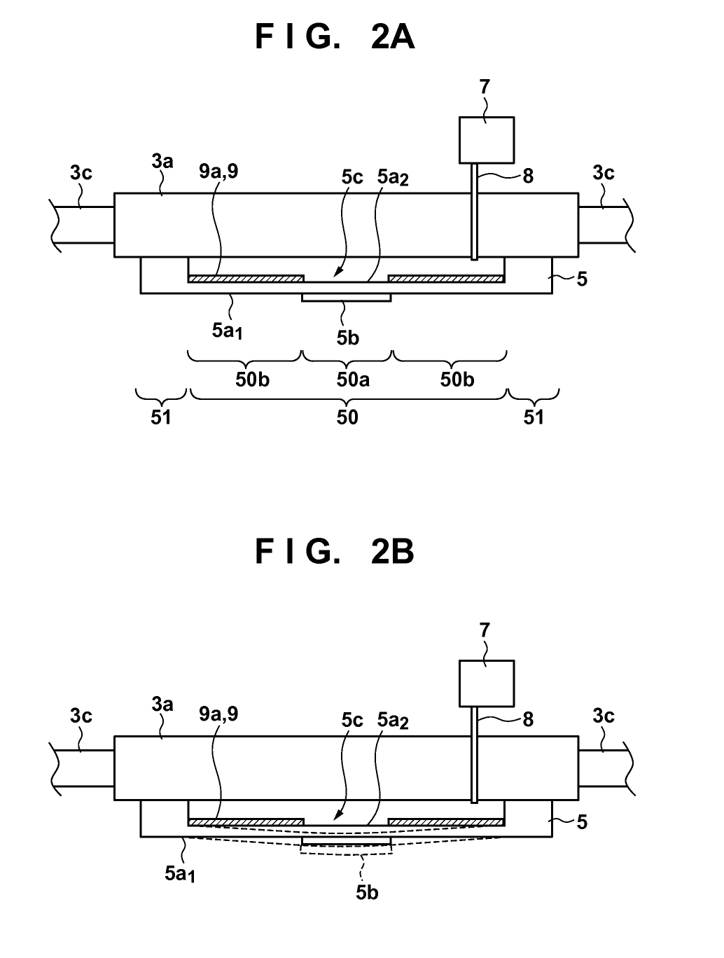

FIG. 1 is a schematic view showing the imprint apparatus 100 according to the first embodiment. The imprint apparatus 100 includes a substrate stage 2 which holds the substrate 1, an imprint head 3 which holds the mold 5, an irradiation unit 6 having a light source which emits light (ultraviolet light (UV)), a measuring unit 11 which measures the relative positions between the mold 5 and the substrate 1, and a control unit 13. The substrate stage 2 is fixed to a base plate 4. The imprint head 3 is fixed to a bridge plate 12 supported by the base plate 4 through a support column (not shown). In addition, the irradiation unit 6 irradiates the resin 14 on the substrate with light (ultraviolet light) through the mold 5 to cure the resin 14. The control unit 13 includes a CPU and a memory and controls an imprint process (controls the respective units of the imprint apparatus 100). The mold 5 will be described with reference to FIGS. 2A and 2B. FIG. 2A is a sectional view of the mold 5 and a mold holding portion 3a. The mold 5 is generally formed from a material that can transmit ultraviolet light, such as quarts. The mold 5 includes a first portion 50 and a second portion 51. The first portion 50 includes a first surface 5a₁ including a pattern portion 50a provided with a pattern 5d and a peripheral portion 50b surrounding the pattern portion 50a and a second surface 5a₂ on the opposite side to the first surface 5a₁. The second portion 51 surrounds the first portion 50 and is thicker than the first portion 50. In the mold 5 having the above arrangement, a concave portion 5c is formed by the second surface 5a₂ of the first portion 50 and the inner surface of the second portion 51. Forming the concave portion 5c in the mold 5 in this manner makes the mold 5 (first surface 5a₁) easily deform when changing the atmospheric pressure in the concave portion 5c. In addition, a protrusive portion 5b (mesa) is formed on a portion of the pattern portion 50a so as to have the concave/convex pattern 5d to be transferred onto the resin 14 on the substrate and protrude toward the substrate 1 (toward the opposite side to the concave portion 5c). In this case, for example, the mold 5 may include a member having a surface covering the concave portion 5c so as to define a space including the concave portion 5c together with the second surface 5a₂ of the first portion 50 and the inner surface of the second portion 51. Covering the concave portion 5c with this member in this manner defines the space including the concave portion 5c with the surface of the member, the second surface 5a₂ of the first portion 50, and the inner surface of the second portion 51. That is, forming the mold 5 in this manner defines the space including the concave portion 5c inside the mold 5.

The imprint head 3 includes the mold holding portion 3a which holds the mold 5 with vacuum absorption force or electrostatic force and a mold driving portion 3b which drives the mold holding portion 3a through a support member 3c in the Z direction. The mold holding portion 3a makes the concave portion 5c of the mold 5 become an almost hermetically sealed space by holding the mold 5 so as to cover the concave portion 5c. The concave portion 5c of the mold 5 which is almost hermetically sealed by the mold holding portion 3a is connected to an atmospheric pressure adjusting unit 7 via a pipe 8. The atmospheric pressure adjusting unit 7 adjusts the atmospheric pressure in the concave portion 5c. The atmospheric pressure adjusting unit 7 includes, for example, a changeover valve for changing over between a source for supplying compressed air to the concave portion 5c and a vacuum source for evacuating the concave portion 5c and a servo valve. The mold driving portion 3b can mechanically support the mold holding portion 3a through the support member 3c and move the mold holding portion 3a (mold 5) in the Z direction by driving the support member 3c in the Z direction.

The control unit 13 controls the atmospheric pressure adjusting unit 7 to increase the atmospheric pressure in the concave portion 5c when, for example, making the mold 5 come into contact with the resin 14 on the substrate. As shown in FIG. 2B, this makes it possible to deform the mold 5 into a convex shape with a first surface 5a bending toward the substrate 1. FIG. 2B is a sectional view showing the mold 5 when it deforms into a convex shape with the first surface 5a bending toward the substrate 1. When the mold 5 comes into contact with the resin 14 on the substrate while the mold 5 is deformed in this manner, the protrusive portion 5b of the mold 5 gradually comes into contact from its central portion to the peripheral side, and hence it is possible to prevent air bubbles from being confined in the pattern 5d of the mold 5. This can prevent the occurrence of a defect in the pattern transferred onto the substrate. In this case, the control unit 13 also controls the atmospheric pressure adjusting unit 7 to gradually decrease the atmospheric pressure in the concave portion 5c as the mold 5 comes into contact with the resin 14 on the substrate from the central portion of the protrusive portion 5b to the peripheral side. This makes it possible to make the first surface 5a become almost flat when the entire pattern 5d of the mold 5 comes into contact with the resin 14 on the substrate. The control unit 13 controls the atmospheric pressure adjusting unit 7 to gradually increase the atmospheric pressure in the concave portion 5c when releasing the mold 5 from the cured resin 14. With this operation, the protrusive portion 5b of the mold 5 is gradually released from the resin 14 from the peripheral side to the central portion. This can also prevent the occurrence of a defect in the pattern transferred onto the substrate in this process.

As the substrate 1, for example, a single-crystal silicon substrate or the like is used. For example, a coating apparatus (resist coater) located outside the imprint apparatus 100 evenly coats the entire upper surface (the surface to be treated) of the substrate 1 with the resin 14 before an imprint process. In this case, the first embodiment performs the process of coating the substrate with the resin 14 by using the coating apparatus outside the imprint apparatus 100. However, the embodiment is not limited to this. For example, the imprint apparatus 100 may be equipped with a coating unit which applies the resin 14 to coat the entire surface of the substrate with the resin 14 in advance before an imprint process.

The substrate stage 2 includes a substrate holding unit 2a and a stage driving unit 2b, and drives the substrate 1 in the X and Y directions. The substrate holding unit 2a holds the substrate 1 with holding force such as vacuum absorption force or electrostatic force. As the stage driving unit 2b, for example, a linear motor is used. The stage driving unit 2b mechanically holds the substrate holding unit 2a and drives the substrate holding unit 2a (substrate 1) in the X and Y directions. The stage driving unit 2b may have a driving function of driving the substrate 1 in the Z direction and the θ direction (a rotating direction around the Z-axis) and a tilt function of correcting the tilt of the substrate 1.

The measuring unit 11 measures the relative positions between the pattern 5d of the mold 5 and a shot region 10 on the substrate in a planar direction (X and Y directions) along the surface of the substrate 1. As a method of measuring the relative positions between the pattern 5d of the mold 5 and the shot region 10, for example, there is available a method of detecting a plurality of alignment marks respectively provided on the pattern on the mold 5 and the shot region 10. The measuring unit 11 detects the relative positions between the alignment mark on the pattern 5d of the mold 5 and the corresponding alignment mark on the shot region 10 at each of the plurality of alignment marks. This enables the measuring unit 11 to measure the relative positions between the pattern 5d of the mold 5 and the shot region in the X and Y directions.

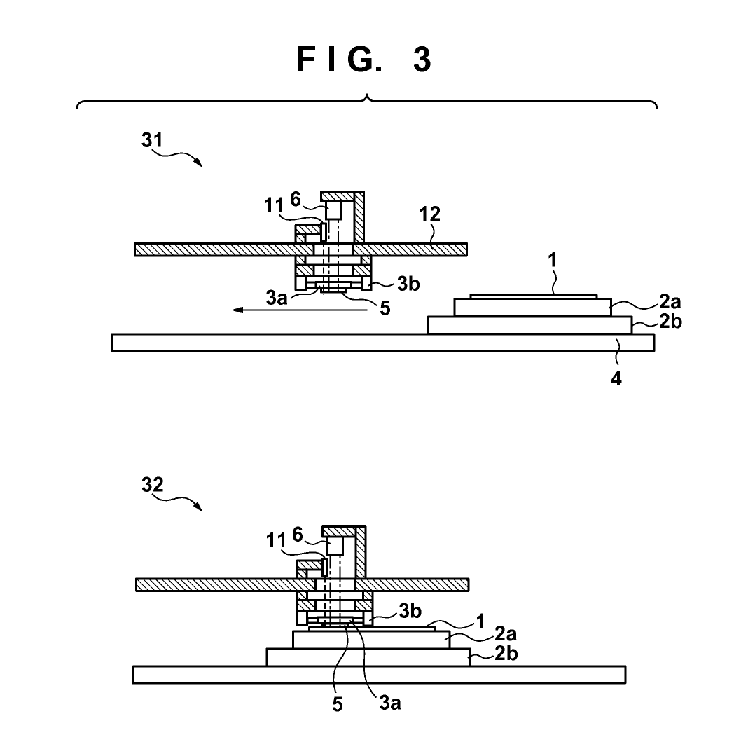

A procedure for an imprint process in the imprint apparatus 100 according to the first embodiment will be described with reference to FIGS. 3 and 4. When the substrate holding unit 2a holds the substrate 1 whose entire surface is coated with resin 14, the control unit 13 controls the stage driving unit 2b to place the shot region 10 onto which the pattern 5d of the mold 5 is to be transferred below the pattern 5d of the mold 5, as indicated by “31” in FIG. 3. When the shot region 10 is placed below the pattern 5d of the mold 5, the control unit 13 controls the mold driving portion 3b to drive the mold 5 in the −Z direction, and makes the mold 5 come into contact with the resin 14 on the substrate, as indicated by “32” in FIG. 3. The control unit 13 keeps the contact state between the mold 5 and the resin 14 on the substrate for a predetermined period of time. This makes it possible to thoroughly fill the pattern 5d of the mold 5 with the resin 14 on the substrate.

As indicated by “41” in FIG. 4, the control unit 13 measures the relative positions between the pattern 5d of the mold 5 and the shot region 10 by using the measuring unit 11 while keeping the mold 5 in contact with the resin 14 on the substrate. After the measurement by the measuring unit 11, the control unit 13 aligns the pattern 5d of the mold 5 with the shot region 10 based on the measurement result obtained by the measuring unit 11. Upon aligning the pattern 5d of the mold 5 with the shot region 10, the control unit 13 controls the irradiation unit 6 to irradiate the resin 14 on the substrate with light (ultraviolet light) through the mold 5, as indicated by “42” in FIG. 4. As indicated by “43” in FIG. 4, the control unit 13 controls the mold driving portion 3b to move the mold 5 in the +Z direction so as to release the mold 5 from the resin 14 on the substrate which is cured by being irradiated with light. This makes it possible to transfer the pattern 5d of the mold 5 onto the resin 14 on the substrate. The control unit 13 performs such an imprint process for each of a plurality of shot regions 10 on the substrate.

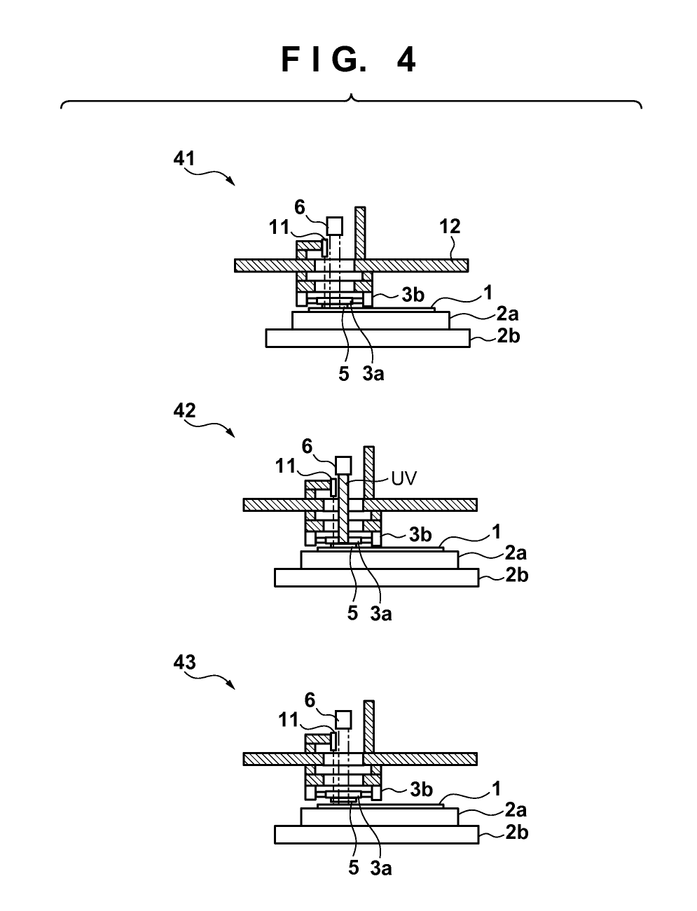

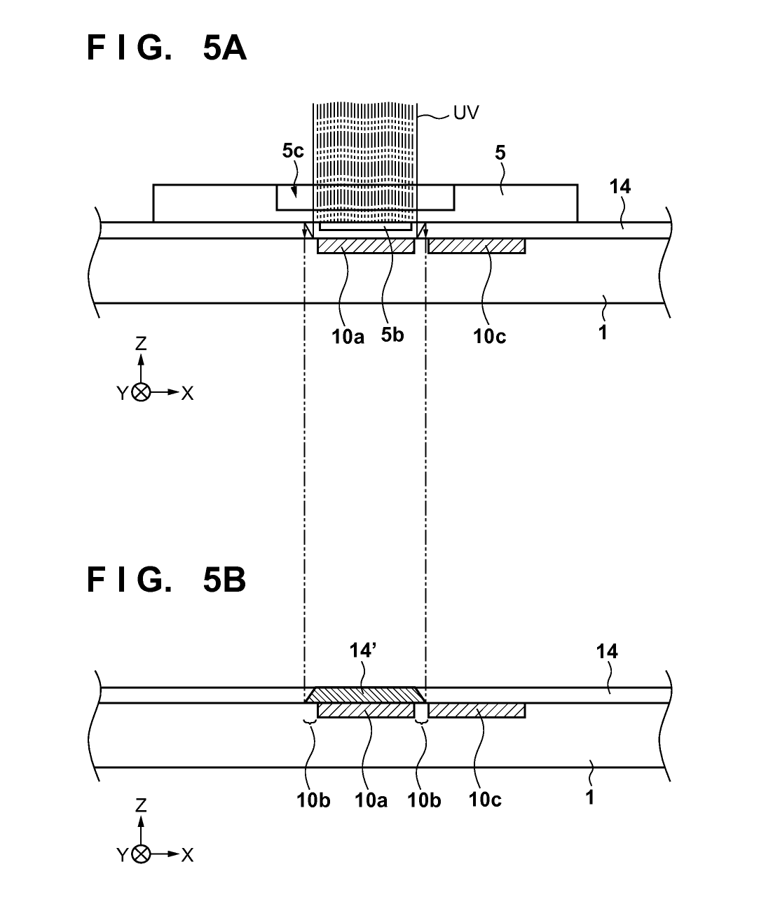

As described above, the imprint apparatus 100 of the first embodiment coats the entire surface of the substrate 1 with the resin 14 in advance, and sequentially performs an imprint process for each of the plurality of shot regions 10 on the substrate 1 whose entire surface is coated with the resin 14. As shown in FIG. 5A, however, when the apparatus applies light to a shot region 10a, of the plurality of shot regions 10, onto which the pattern 5d of the mold 5 is to be transferred, the peripheral portion is also irradiated with the light or the light is diffused between the substrate 1 and the mold 5. As a result, as shown in FIG. 5B, the light cures not only the resin 14 applied to the shot region 10a but also the resin 14 applied to a peripheral region 10b of the shot region 10a. In this case, referring to FIG. 5B, a hatched portion 14′ indicates the resin 14 cured by being irradiated with light, and the oblique portion of the hatched portion 14′ indicate that the resin 14 is half cured. In addition, the imprint apparatus 100 of the first embodiment coats the entire surface of the substrate 1 with the resin. However, the embodiment is not limited to this. For example, the resin may be applied to at least the shot region 10a onto which the pattern 5d of the mold 5 is to be transferred and the peripheral region 10b.

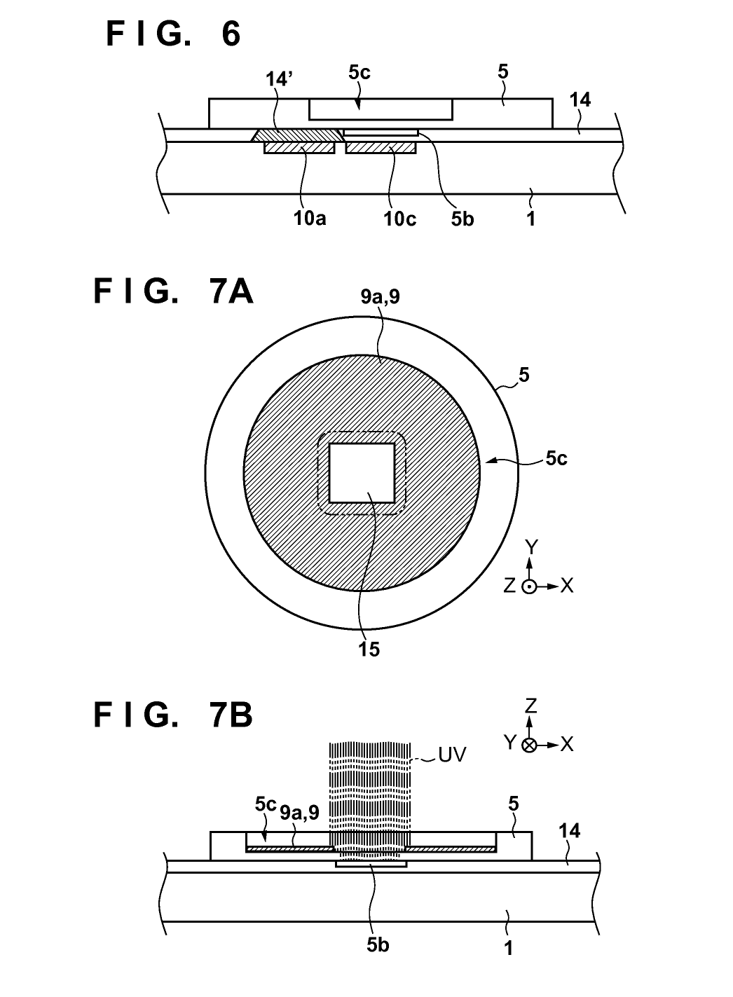

Assume that the resin 14 in the peripheral region 10b is cured in this manner. In this case, when the apparatus performs an imprint process for a shot region 10c adjacent to the shot region 10a, the protrusive portion 5b of the mold 5 can collide with the cured resin 14′ in the peripheral region 10b, as shown in FIG. 6. In this case, for example, problems occur, including that the mold 5 comes into contact with the resin 14 on the substrate in a tilted state or the relative positions between the mold 5 and the substrate 1 in the X and Y directions cannot be changed while the mold 5 is in contact with the resin 14. That is, when transferring the pattern 5d of the mold 5 onto the shot region 10c, it may be difficult to accurately align the mold 5 with the substrate 1 because of the influence of the curing of the resin 14 in the peripheral region 10b.

For this reason, as shown in FIG. 2A, in the concave portion of the mold 5 according to the first embodiment, a light-shielding portion 9 is provided on a region on the opposite side to the peripheral portion 50b. The light-shielding portion 9 is configured to make light entering the concave portion 5c be transmitted through the pattern 5d formed on the protrusive portion 5b and part of the protrusive portion 5b on the peripheral portion. The first embodiment includes, for example, a light-shielding film 9a formed from a metal film provided as the light-shielding portion 9 on the second surface 5a₂ of the mold 5. The metal film can be made of a material containing one or more types of elements of a metal group including, for example, chromium, titanium, tantalum, tungsten, vanadium, molybdenum, cobalt, niobium, iron, copper, zinc, and aluminum. It is possible to form the metal film by a thin film forming method such as a sputtering method, plating method, or vapor deposition method. In this case, in the first embodiment, the light-shielding film 9a is formed from a metal film. However, the embodiment is not limited to this. It is only required to shield light which cures the resin 14 on the substrate.

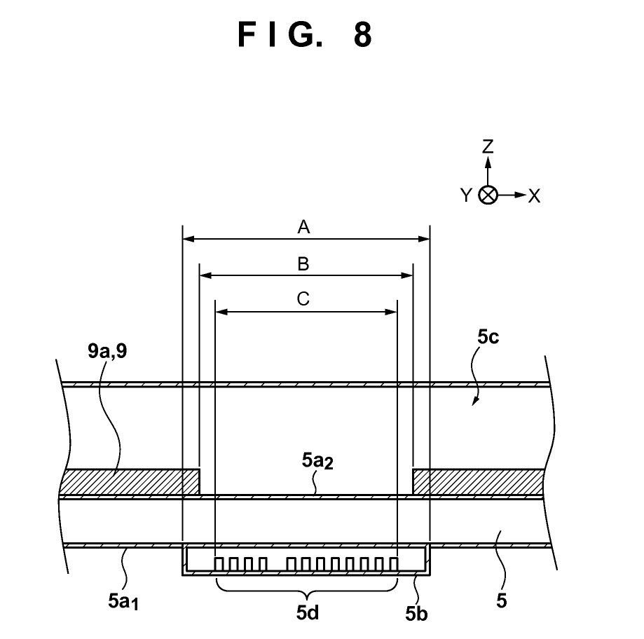

The light-shielding film 9a provided as the light-shielding portion 9 in the concave portion 5c of the mold 5 will be described with reference to FIGS. 7A, 7B, and 8. FIGS. 7A and 7B are views showing the mold 5 used in the imprint apparatus 100 according to the first embodiment. FIG. 7A is a view showing the mold 5 when viewed from the Z direction. Referring to FIG. 7A, the chain double-dashed line indicates an area to be irradiated with light emitted from the irradiation unit 6. FIG. 7B is a view showing a state in which the mold 5 is made to come into contact with the resin 14 on the substrate, and the resin 14 on the substrate is irradiated with light through the mold 5. As described above, the light-shielding film 9a is configured to make light entering the concave portion 5c be transmitted through the pattern 5d formed on the protrusive portion 5b and part of the protrusive portion 5b on the peripheral portion. Making the light be transmitted through the pattern 5d and its peripheral portion can prevent the peripheral region 10b of the shot region 10a from being irradiated with light. The light-shielding film 9a has an opening portion 15 which makes light be transmitted through the pattern 5d and its peripheral portion, and is configured to inhibit light from being transmitted through any portion other than the opening portion 15.

In addition, FIG. 8 is a view showing the size of the opening portion 15 of the light-shielding film 9a. Sizes in the X direction will be described below. However, the same applies to sizes in the Y direction. Referring to FIG. 8, the size of the protrusive portion 5b, the size of the opening portion 15 of the light-shielding film 9a, and the size of the pattern 5d formed on the protrusive portion 5b in the X direction are respectively represented by A, B, and C. In this case, the light-shielding film 9a is formed such that the size B of the opening portion 15 is set between the size A of the protrusive portion 5b and the size C of the pattern 5d. Forming the light-shielding film 9a in this manner enables the imprint apparatus 100 to apply light to the shot region 10a onto which the pattern 5d is to be transferred and prevent the peripheral region 10b from being irradiated with light. When performing an imprint process for the shot region 10b adjacent to the shot region 10a, the apparatus can suppress the influence of the resin 14 cured in the peripheral region 10b and accurately transfer the pattern 5d of the mold 5 onto the shot region 10b.

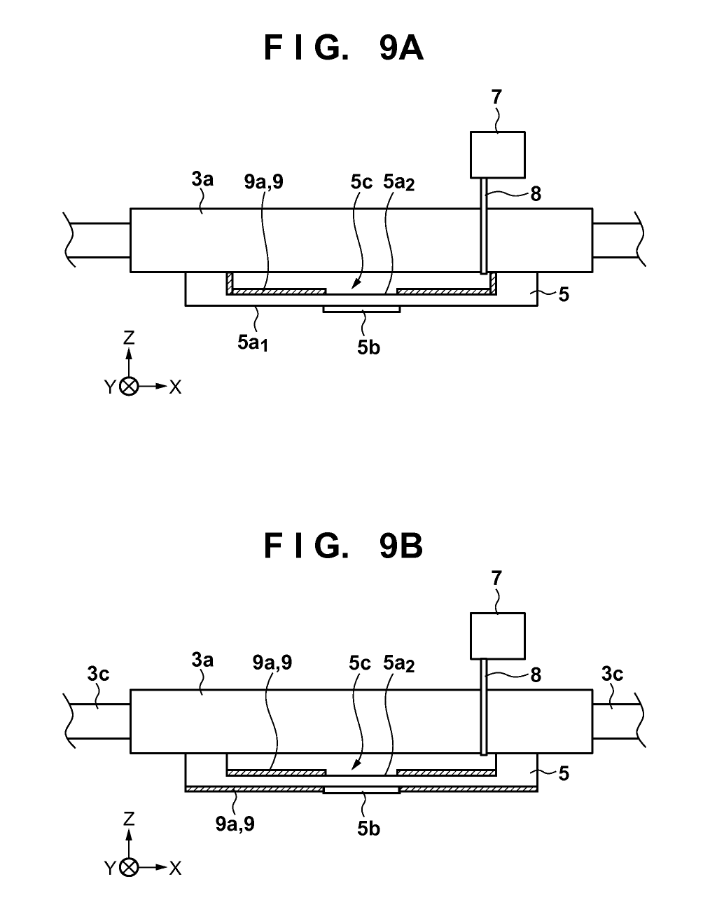

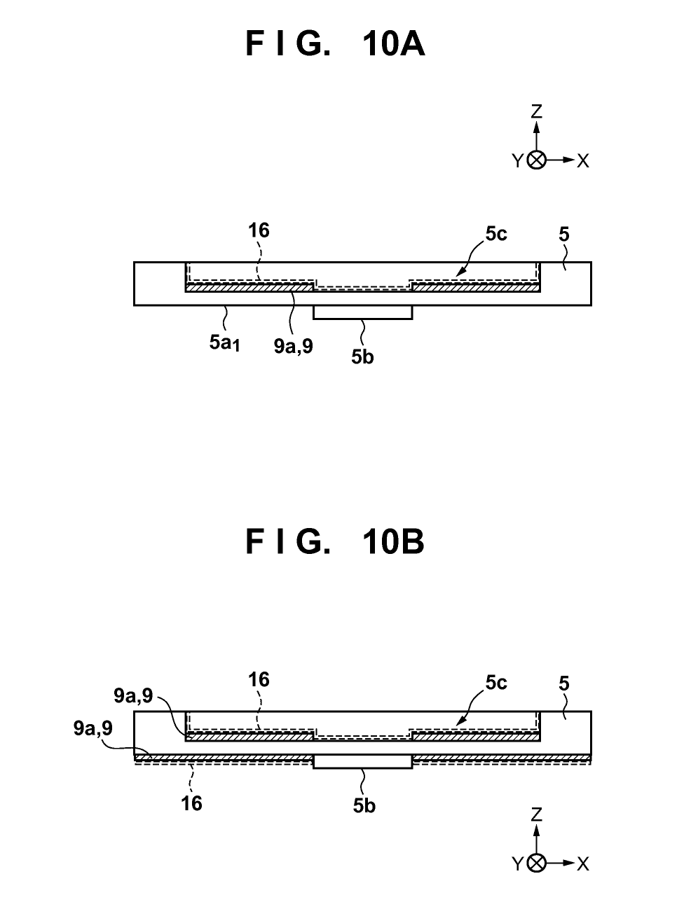

In this case, for example, the light-shielding film 9a may be formed on a side surface (the inner surface of the second portion) of the concave portion 5c of the mold 5 as shown in FIG. 9A or on the first surface 5a (other than the protrusive portion 5b) of the mold 5 as shown in FIG. 9B. Forming the light-shielding film 9a in this manner can further prevent the peripheral region 10b of the shot region 10a from being irradiated with light. In addition, as shown in FIGS. 10A and 10B, the light-shielding film 9a may be covered with a protective film 16. Covering the light-shielding film 9a with the protective film 16 in this manner makes it possible to prevent the light-shielding film 9a from peeling off, being chipped, or decreasing in thickness when washing the mold 5 and to stably shield light by using the light-shielding film 9a. For example, as the protective film 16, silicon dioxide (SiO₂) or the like is used.

As described above, in the concave portion of the mold 5 in the first embodiment, the light-shielding film 9a is provided in a region on the opposite side to the peripheral portion 50b. The light-shielding film 9a is configured to make light entering the concave portion 5c be transmitted through the pattern 5d formed on the protrusive portion 5b and part of the protrusive portion 5b on the surrounding portion. This can prevent the peripheral region 10b of the shot region 10a from being irradiated with light. That is, it is possible to accurately transfer the pattern 5d of the mold 5 onto the shot region 10b by suppressing the influence of the resin 14 cured in the peripheral region 10b in an imprint process for the shot region 10b adjacent to the shot region 10a having undergone an imprint process.

### Second Embodiment

An imprint apparatus according to the second embodiment of the present invention will be described. In the first embodiment, the light-shielding portion 9 is formed as the light-shielding film 9a provided on the second surface 5a₂ of the mold 5. In contrast to this, in the second embodiment, a light-shielding portion 9 is formed as a light-shielding member 9b configured to be detachable from a concave portion 5c of a mold 5. The light-shielding member 9b formed as the light-shielding portion 9 will be described below. Since the arrangement of the imprint apparatus according to the second embodiment is the same as that of the imprint apparatus 100 according to the first embodiment except for the light-shielding portion 9, a description of the apparatus arrangement except for the light-shielding portion 9 will be omitted.

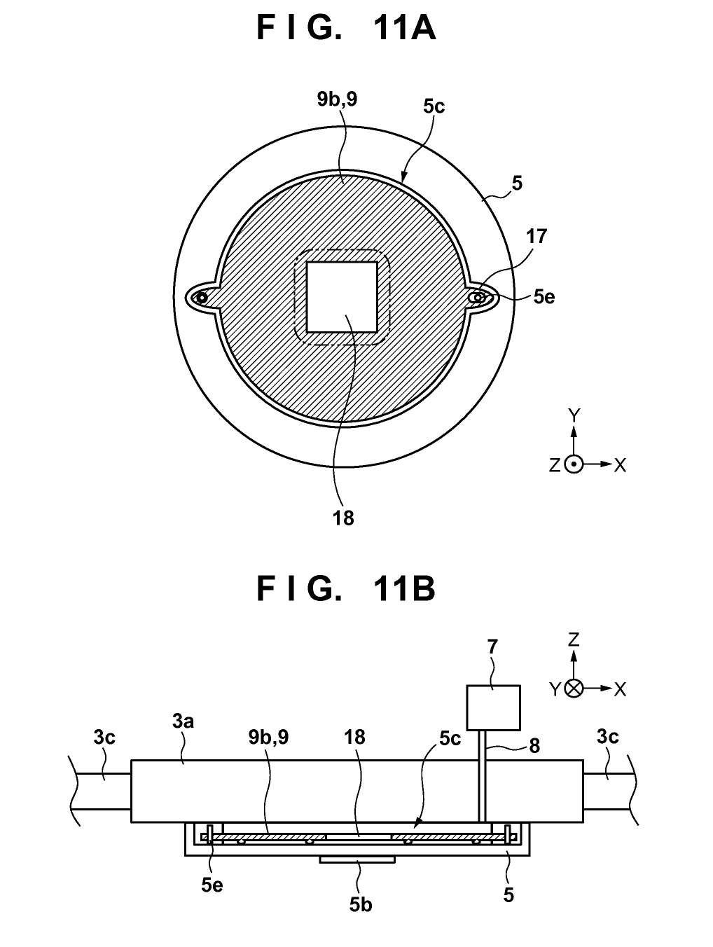

FIGS. 11A and 11B are views showing the mold 5 and the light-shielding member 9b used in the imprint apparatus of the second embodiment. FIG. 11A is a view showing the mold 5 and the light-shielding member 9b when viewed from above. FIG. 11B is a sectional view of the mold 5, the light-shielding member 9b, and a mold holding portion 3a. As described above, the light-shielding member 9b is configured to be detachable from the concave portion 5c of the mold 5. As the light-shielding member 9b, for example, a metal plate is used. The light-shielding member 9b has a through hole 17 at a position corresponding to a pin 5e provided on the concave portion 5c of the mold 5. The light-shielding member 9b is fixed by making the pin 5e provided on the concave portion 5c extend through the through hole 17, and can make a shift amount relative to the mold 5 along a planar direction (X and Y directions) parallel to the surface of the substrate 1 fall within an allowable range. When forming the light-shielding member 9b in this manner, it is possible to make a shift amount relative to the mold 5 in the X and Y directions fall within an allowable range of ±5 μm.

The light-shielding member 9b has an opening portion 18 which transmits light emitted from the irradiation unit 6. The opening portion 18 can be formed to have a size B between a size A of the protrusive portion 5b and a size C of a pattern 5d as in the light-shielding portion 9 of the first embodiment. Forming the light-shielding member 9b in this manner enables an imprint apparatus 100 to apply light to a shot region 10a onto which the pattern 5d is to be transferred and prevent a peripheral region 10b from being irradiated with light. As in the first embodiment, therefore, it is possible to suppress the influence of a resin 14 cured in the peripheral region 10b of the shot region 10a when performing an imprint process in a shot region 10c adjacent to the shot region 10a having undergone an imprint process. It is therefore possible to accurately transfer the pattern 5d of the mold 5 onto the peripheral region 10b on the substrate. In this case, the light-shielding member 9b as the light-shielding portion 9 may be formed by using a member which transmits light, such as quarts, so as to form a metal film on a portion other than the opening portion 18.

As described above, the imprint apparatus according to the second embodiment uses, as the light-shielding portion 9, the light-shielding member 9b configured to be detachable from the concave portion 5c of the mold 5. The light-shielding member 9b has the opening portion 18 configured to make light entering the concave portion 5c be transmitted through the pattern 5d and its peripheral portion. Using the light-shielding member 9b configured in this manner as the light-shielding portion 9 can detach the light-shielding member 9b from the mold 5 when washing the mold 5. In this case, it is possible to use both the light-shielding film 9a used as the light-shielding portion 9 in the first embodiment and the light-shielding member 9b used as the light-shielding portion 9 in the second embodiment.

### Embodiment of Method of Manufacturing Article

A method of manufacturing an article according to an embodiment of the present invention is suitable for manufacturing an article such as a microdevice such as a semiconductor device or an element having a microstructure. This method of manufacturing articles according to this embodiment can include a step of forming a pattern on a resin applied on a substrate by using the above imprint apparatus (a step of performing an imprint process on a substrate) and a step of processing the substrate on which the pattern has been formed in the preceding step. The manufacturing method can further include other known steps (oxidation, film formation, deposition, doping, planarization, etching, resist removal, dicing, bonding, packaging, and the like). The method of manufacturing an article according to this embodiment is superior to the conventional method in at least one of the performance of an article, quality, productivity, and production cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-134209 filed on Jun. 26, 2013, which is hereby incorporated by reference herein in its entirety.

What is claimed is:

1. A mold including a pattern to be transferred to a resin coated on a substrate, by performing an imprint process, the mold comprising:
a first portion including a first surface which include a pattern portion provided with the pattern and a peripheral portion surrounding the pattern portion, and a second surface which is opposite to the first surface; and
a second portion which surrounds the first portion and is thicker than the first portion,
wherein a concave portion is formed by the second surface of the first portion and an inner surface of the second portion, and
the concave portion is provided with a light-shielding portion in a region on an opposite side to the peripheral portion.

2. The mold according to claim 1, wherein the pattern portion is provided with a protrusive portion protruding in a direction to an opposite side to the concave portion, and
the pattern is formed on the protrusive portion.

3. The mold according to claim 2, wherein the light-shielding portion is configured to make light be transmitted through the pattern formed on the protrusive portion and part of the protrusive portion at a portion around the pattern.

4. The mold according to claim 1, wherein the light-shielding portion is covered with a protective film.

5. The mold according to claim 1, wherein the light-shielding portion is configured to be detachable from the concave portion.

6. The mold according to claim 5, wherein the light-shielding portion is fixed to the mold by making a pin provided on the concave portion extend through a through hole formed in the light-shielding portion.

7. The mold according to claim 1, further comprising a member including a surface covering the concave portion so as to define a space including the concave portion, together with the second surface of the first portion and the inner surface of the second portion.
